(19) United States
(12) Patent Application Publication
(10) Pub. No.: US 2024/0222585 A1
(43) Pub. Date: Jul. 4, 2024

(54) DISPLAY DEVICE

(71) Applicant: LG Display Co., Ltd., Seoul (KR)

(72) Inventors: EunHye LEE, Paju-si (KR); GiSang HONG, Seoul (KR); Hyeonchul IM, Gimpo-si (KR)

(73) Assignee: LG Display Co., Ltd., Seoul (KR)

(21) Appl. No.: 18/396,510

(22) Filed: Dec. 26, 2023

(30) Foreign Application Priority Data
Dec. 28, 2022 (KR) 10-2022-0187101

(51) Int. Cl. H01L 33/62; H01L 25/16

(52) U.S. Cl. CPC H01L 33/62; H01L 25/167

(57) ABSTRACT

According to an aspect of the present disclosure, a display device includes a substrate in which a plurality of sub pixels is defined; a light emitting diode disposed on the substrate in each of the plurality of sub pixels; and a planarization layer which covers the light emitting diode and includes a first contact hole overlapping the light emitting diode. The first contact hole is formed to have a width which is narrowed from an upper portion of the first contact hole toward a lower portion of the first contact hole. Accordingly, the first contact hole is formed to have a step shape so that the exposure of the side surface part of the light emitting diode through the first contact hole and the disconnection of the pixel electrode may be minimized.

### CROSS-REFERENCE TO RELATED APPLICATIONS

This application claims the priority of Korean Patent Application No. 10-2022-0187101 filed on Dec. 28, 2022, in the Korean Intellectual Property Office, the disclosure of which is incorporated herein by reference.

### BACKGROUND

### Technical Field

The present disclosure relates to a display device, and more particularly, to a display device which self-assembles a light emitting diode (LED).

### Discussion of the Related Art

As display devices which are used for a monitor of a computer, a television, or a cellular phone, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, in recent years, a display device including an LED is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

Accordingly, embodiments of the present disclosure are directed to a display device that substantially obviates one or more of the problems due to limitations and disadvantages of the related art.

An aspect of the present disclosure is to provide a display device in which a disconnection of a pixel electrode is minimized in a contact hole.

Another aspect of the present disclosure is to provide a display device in which a first contact hole above the light emitting diode is designed in various forms.

Still another aspect of the present disclosure is to provide a display device in which a contact hole is formed in a micro size.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate in which a plurality of sub pixels is defined; a light emitting diode disposed on the substrate in each of the plurality of sub pixels; and a planarization layer which covers the light emitting diode and includes a first contact hole overlapping the light emitting diode. The first contact hole is formed to have a width which is narrowed from an upper portion of the first contact hole toward a lower portion of the first contact hole. Accordingly, the first contact hole is formed to have a step shape so that the exposure of the side surface part of the light emitting diode through the first contact hole and the disconnection of the pixel electrode may be minimized.

Other detailed matters of the exemplary embodiments are included in the detailed description and the drawings.

According to the present disclosure, the exposure of the side surface of the light emitting diode through the contact hole may be minimized.

According to the present disclosure, disconnection of the pixel electrode in the contact hole may be minimized.

According to the present disclosure, contact holes having various shapes may be formed with one mask so that a manufacturing cost may be saved.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is a plan view of a display panel of a display device according to an exemplary embodiment of the present disclosure;

FIG. 4 is an enlarged plan view of an active area of a display device according to an exemplary embodiment of the present disclosure;

FIG. 5 is a cross-sectional view taken along the lines A-A′ and B-B′ of FIG. 4;

FIG. 6 is an enlarged plan view of a non-active area of a display device according to an exemplary embodiment of the present disclosure;

FIG. 7 is a view for explaining a forming process of a first contact hole of a display device according to an exemplary embodiment of the present disclosure;

FIG. 8 is a schematic plan view of a display device according to another exemplary embodiment of the present disclosure;

FIG. 9 is a schematic plan view of a display device according to still another exemplary embodiment of the present disclosure; and

FIG. 10 is a schematic plan view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

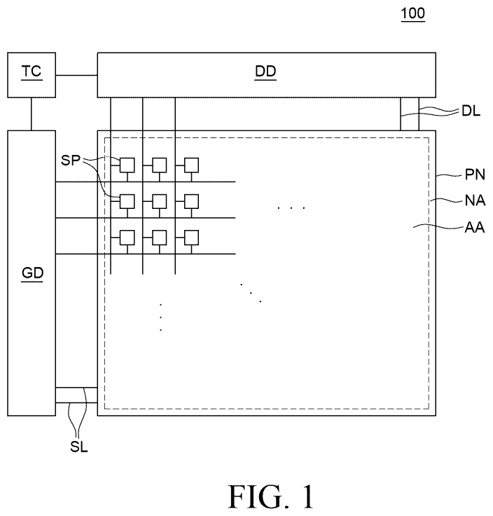

FIG. 1 is a schematic diagram of a display device according to an exemplary embodiment of the present disclosure. In FIG. 1, for the convenience of description, among various components of the display device, only a display panel PN, a gate driver GD, a data driver DD, and a timing controller TC are illustrated.

Referring to FIG. 1, the display device includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL in accordance with a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD supplies a data voltage to a plurality of data lines DL according to a plurality of data control signals and image data provided from the timing controller TC. The data driver DD may convert the image data into a data voltage using a reference gamma voltage and supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP may be formed at intersections of the scan lines SL and the data lines DL.

In the display panel PN, an active area AA and a non-active area NA may be defined.

The active area AA is an area in which images are displayed in the display device 100. In the active area AA, a plurality of sub pixels SP which configures a plurality of pixels PX and a pixel (PX) circuit for driving the plurality of sub pixels SP may be disposed. The plurality of sub pixels SP is a minimum unit which configures the active area AA and n sub pixels SP may form one pixel PX. In each of the plurality of sub pixels SP, a thin film transistor for driving the plurality of light emitting diodes 130 may be disposed. The plurality of light emitting diodes 130 may be defined in different ways depending on the type of the display panel PN. For example, when the display panel PN is an inorganic light emitting display panel, the light emitting diode 130 may be a light emitting diode (LED) or a micro light emitting diode (LED).

In the active area AA, a plurality of signal lines which transmits various signals to the plurality of sub pixels SP is disposed. For example, the plurality of signal lines may include a plurality of data lines DL which supplies a data voltage to each of the plurality of sub pixels SP and a plurality of scan lines SL which supplies a scan signal to each of the plurality of sub pixels SP. The plurality of scan lines SL extends in one direction in the active area AA to be connected to the plurality of sub pixels SP and the plurality of data lines DL extends in a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line LL which transmits a signal to the sub pixel SP of the active area AA, a pad electrode PAD, driving IC, such as a gate driver IC or a data driver IC, or the like may be disposed.

In the meantime, the non-active area NA may be located on a rear surface of the display panel PN, that is, a surface on which the sub pixels SP are not disposed or may be omitted, and is not limited as illustrated in the drawing.

A driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner.

For example, the data driver DD and the timing controller TC are formed in separate flexible film and printed circuit board 110 and the display panel PN may be electrically connected to the data driver DD and the timing controller TC by bonding the flexible film and printed circuit board 110 to the pad electrode PAD formed in the non-active area NA of the display panel PN.

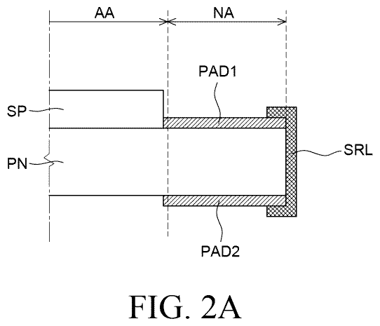

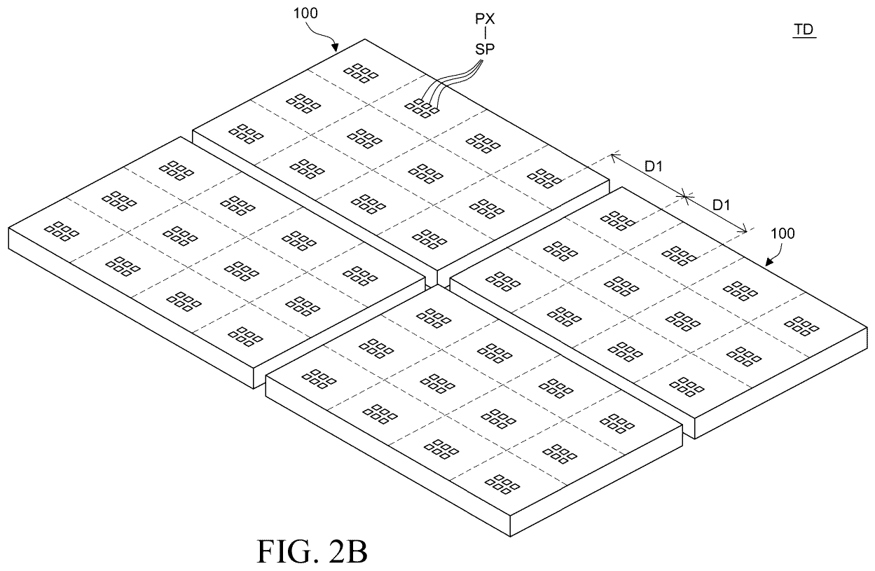

As another example, when the gate driver GD is mounted in the active area AA in the GIA manner and a side line SRL which connects the signal line on the front surface of the display panel PN to the pad electrode PAD on a rear surface of the display panel PN is formed to bond the flexible film and the printed circuit board 110 onto a rear surface of the display panel PN, the non-active area NA on the front surface of the display panel PN may be minimized. Therefore, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes PAD for transmitting various signals to the plurality of sub pixels SP is disposed. For example, in the non-active area NA of the front surface of the display panel PN, a first pad electrode PAD1 which transmits a signal to the plurality of sub pixels SP is disposed. In the non-active area NA of the rear surface of the display panel PN, a second pad electrode PAD2 which is electrically connected to a driving component such as a flexible film and the printed circuit board 110 is disposed.

In this case, even though it is not illustrated in the drawing, various signal lines connected to the plurality of sub pixels SP, for example, a scan line SL, a data line DL, or the like extends from the active area AA to the non-active area NA to be electrically connected to the first pad electrode PAD1.

The side line SRL is disposed along a side surface of the display panel PN. The side line SRL may electrically connect a first pad electrode PAD1 on the front surface of the display panel PN and a second pad electrode PAD2 on the rear surface of the display panel PN. Therefore, a signal from a driving component on the rear surface of the display panel PN may be transmitted to the plurality of sub pixels SP through the second pad electrode PAD2, the side line SRL, and the first pad electrode PAD1. Accordingly, a signal transmitting path from the front surface of the display panel PN to the side surface and the rear surface is formed to minimize an area of the non-active area NA on the front surface of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, the distance between pixels PX between the display devices 100 is constantly configured to minimize the seam area.

However, FIGS. 2A and 2B are illustrative so that the display device 100 according to the exemplary embodiment of the present disclosure may be a general display device 100 with a bezel, but is not limited thereto.

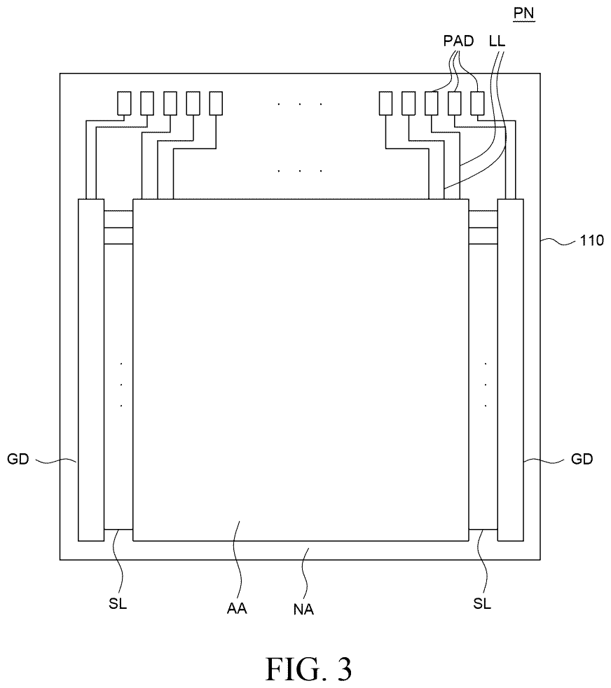

Hereinafter, a display panel PN of a display device 100 according to the exemplary embodiment of the present disclosure will be described in more detail with reference to FIGS. 3 to 7.

FIG. 3 is a plan view of a display panel of a display device according to an exemplary embodiment of the present disclosure.

Referring to FIG. 3, as described above, the display panel PN includes an active area AA in which a plurality of sub pixels SP is disposed to display images and a non-active area NA which extends from the active area AA to dispose various driving circuits for driving the plurality of sub pixels SP.

The gate driver GD may be mounted in the non-active area NA of the display panel PN. The gate driver GD may be disposed in any one of non-active areas NA on both sides of the active area AA. The gate driver GD is connected to the scan line SL extending from the active area AA to supply a scan signal to the scan line SL. Even though in FIG. 3, it is illustrated that the gate drivers GD are disposed on both sides of the active area AA, the gate driver GD may be disposed only in one side of the active area AA, but is not limited thereto.

A plurality of pad electrodes PAD is disposed in the non-active area NA of the display panel PN. The plurality of pad electrodes PAD may be disposed in the non-active area NA above the active area AA, among the non-active areas. The plurality of pad electrodes PAD is electrodes which are connected to an external driving element, such as a flexible film and various signals from the external driving element may be supplied to the wiring lines of the active area AA and the gate driver GD through the plurality of pad electrodes PAD.

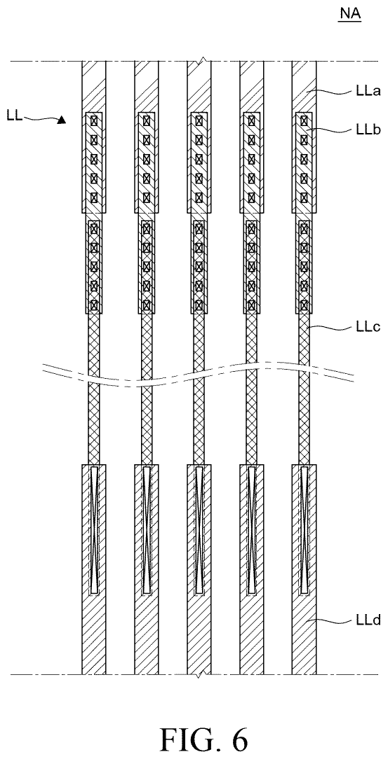

A plurality of link lines LL is disposed in the non-active area NA of the display panel PN. The plurality of link lines LL is a wiring line which is connected to the plurality of pad electrodes PAD to transmit a signal from the plurality of pad electrodes PAD to the gate driver GD or the active area AA. The plurality of link lines LL may electrically connect the plurality of pad electrodes PAD and the wiring lines disposed in the active area AA or may electrically connect the plurality of pad electrodes and the gate driver GD. The plurality of link lines LL may be formed by the same process with the same material as configurations disposed in the active area AA and will be described in more detail with reference to FIG. 6.

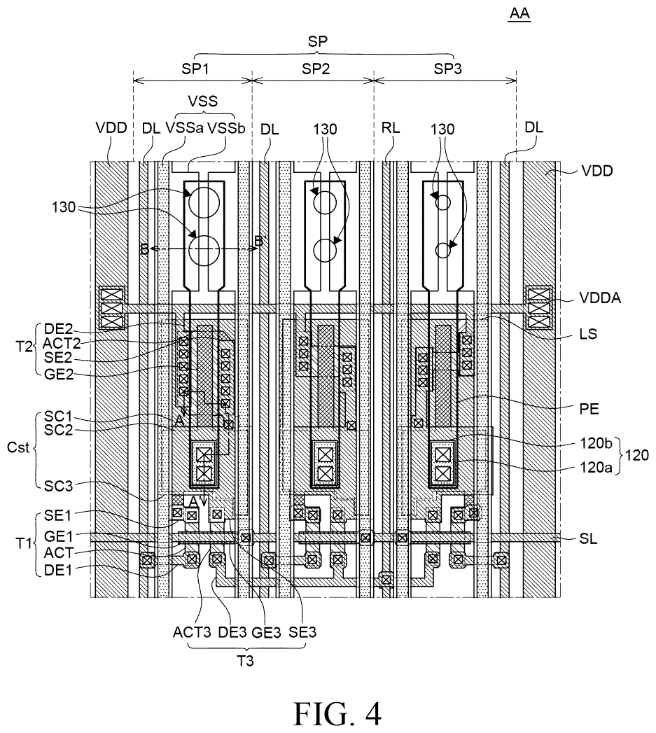

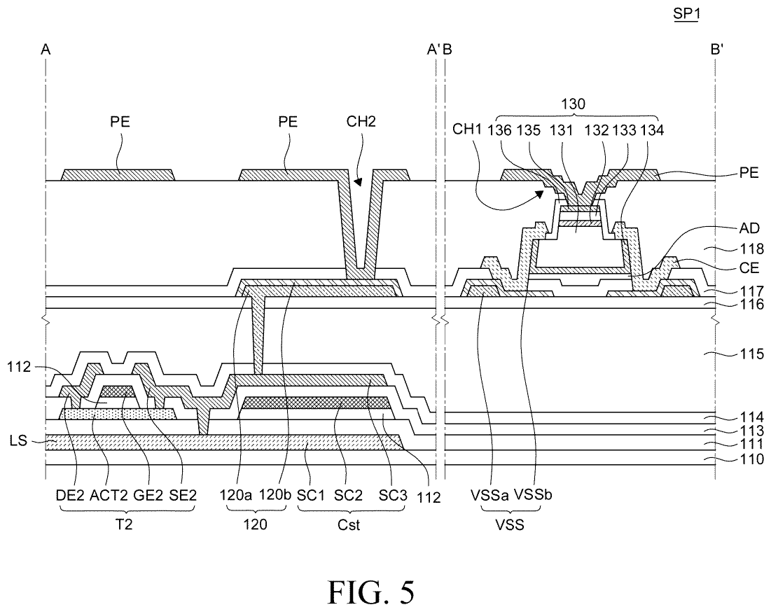

A plurality of sub pixels SP of the active area AA will be described below in detail with reference to FIGS. 4 and 5.

FIG. 4 is an enlarged plan view of an active area of a display device according to an exemplary embodiment of the present disclosure. FIG. 5 is a cross-sectional view taken along the lines A-A′ and B-B′ of FIG. 4. FIG. 6 is an enlarged plan view of a non-active area of a display device according to an exemplary embodiment of the present disclosure. In FIG. 4, for the convenience of description, the hatching of a clad layer VSSb, a pixel electrode PE, and a light emitting diode 130 is omitted and the contact electrode CE is not illustrated.

Referring to FIGS. 4 and 5, each of the plurality of sub pixels SP includes a first transistor T1, a second transistor T2, a third transistor T3, a storage capacitor Cst, and one or more light emitting diodes 130.

The plurality of sub pixels SP may be connected to a plurality of scan lines SL, a plurality of data lines DL, a plurality of reference lines RL, a plurality of high potential power lines VDD, and a plurality of low potential power lines VSS.

The plurality of sub pixels SP includes a first sub pixel SP1, a second sub pixel SP2, and a third sub pixel SP3. Each of the first sub pixel SP1, the second sub pixel SP2, and the third sub pixel SP3 includes a light emitting diode 130 and a pixel PX circuit to independently emit light. For example, the first sub pixel SP1 is a red sub pixel, the second sub pixel SP2 is a green sub pixel, and the third sub pixel SP3 is a blue sub pixel, but the exemplary embodiment is not limited thereto.

Referring to FIG. 5, the substrate 110 is a component for supporting various components included in the display device 100 and may be formed of an insulating material. For example, the substrate 110 may be formed of glass, resin, or the like. Further, the substrate 110 may be configured to include polymer or plastics or may be formed of a material having flexibility.

A high potential power line VDD, a plurality of data lines DL, a reference line RL, a light shielding layer LS, and a first capacitor electrode SC1 are disposed on the substrate 110.

The high potential power line VDD is a wiring line which transmits a high potential power voltage to each of the plurality of sub pixels SP. The plurality of high potential power lines VDD may transmit the high potential power voltage to the second transistor T2 of each of the plurality of sub pixels SP. The high potential power line VDD may extend along a column direction between the plurality of sub pixels SP. For example, the high potential power line VDD may be disposed to extend along a column direction between the first sub pixel SP1 and the third sub pixel SP3. The high potential power line VDD may transmit a high potential power voltage to each of the plurality of sub pixels SP disposed in the row direction through an auxiliary high potential power line VDDA to be described below.

The plurality of data lines DL is wiring lines which transmit the data voltage to each of the plurality of sub pixels SP. The plurality of data lines DL may be connected to the first transistor T1 of each of the plurality of sub pixels SP. The plurality of data lines DL may extend along a column direction between the plurality of sub pixels SP. For example, a data line DL which extends between the first sub pixel SP1 and the high potential power line VDD in the column direction may transmit a data voltage to the first sub pixel SP1. A data line DL disposed between the first sub pixel SP1 and the second sub pixel SP2 may transmit a data voltage to the second sub pixel SP2. Further, a data line DL disposed between the third sub pixel SP3 and the high potential power line VDD may transmit a data voltage to the third sub pixel SP3.

The reference line RL is a wiring line which transmits a reference voltage to the plurality of sub pixels SP. The reference line RL may be connected to the third transistor T3 of each of the plurality of sub pixels SP. The reference line RL may extend along a column direction between the plurality of sub pixels SP. For example, the reference line RL may be disposed to extend along a column direction between the second sub pixel SP2 and the third sub pixel SP3. A third drain electrode DE3 of the third transistor T3 of each of the first sub pixel SP1, the second sub pixel SP2, and the third sub pixel SP3 adjacent to the reference line RL extends in the row direction to be electrically connected to the reference line RL.

The light shielding layer LS is disposed on the substrate 110 in each of the plurality of sub pixels SP. The light shielding layer LS blocks light which is incident to the transistor from the lower portion of the substrate 110 to minimize a leakage current. For example, the light shielding layer LS may block light incident to a second active layer ACT2 of the second transistor T2 which is a driving transistor.

In each of the plurality of sub pixels SP, a first capacitor electrode SC1 is disposed on the substrate 110. The first capacitor electrode SC1 may form a storage capacitor Cst together with the other capacitor electrode. The first capacitor electrode SC1 may be integrally formed with the light shielding layer LS.

A buffer layer 111 is disposed on the high potential power line VDD, the plurality of data lines DL, the reference line RL, the light shielding layer LS, and the first capacitor electrode SC1. The buffer layer 111 may reduce permeation of moisture or impurities through the substrate 110. The buffer layer 111 may be configured by a single layer or a double layer of silicon oxide SiOx or silicon nitride SiNx, but is not limited thereto. However, the buffer layer 111 may be omitted depending on a type of substrate 110 or a type of transistor, but is not limited thereto.

First, the first transistor T1 is disposed on the buffer layer 111 in each of the plurality of sub pixels SP. The first transistor T1 is a transistor which transmits a data voltage to the second gate electrode GE2 of the second transistor T2. The first transistor T1 may be turned on by a scan signal from the scan line SL and a data voltage from the data line DL may be transmitted to the second gate electrode GE2 of the second transistor T2 through the turned-on first transistor T1. Accordingly, the first transistor T1 may be referred to as a switching transistor.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be formed of a semiconductor material such as an oxide semiconductor, amorphous silicon, or polysilicon, but is not limited thereto.

The gate insulating layer 112 is disposed on the first active layer ACT1. The gate insulating layer 112 is an insulating layer which insulates the first active layer ACT1 from the first gate electrode GE1 and may be configured by a single layer or a double layer of silicon oxide (SiOx) or silicon nitride (SiNx), but is not limited thereto.

The first gate electrode GE1 is disposed on the gate insulating layer 112. The first gate electrode GE1 may be electrically connected to the scan line SL. The first gate electrode GE1 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the first gate electrode GE1. A contact hole is formed in the interlayer insulating layer 113 to allow each of the first source electrode SE1 and the first drain electrode DE1 to be connected to the first active layer ACT1. The interlayer insulating layer 113 is an insulating layer which protects components below the interlayer insulating layer 113 and may be configured by a single layer or a double layer of silicon oxide SiOx or silicon nitride SiNx, but is not limited thereto.

A first source electrode SE1 and a first drain electrode DE1 which are electrically connected to the first active layer ACT1 are disposed on the interlayer insulating layer 113. The first drain electrode DE1 may be connected to the data line DL and the first active layer ACT1 and the first source electrode SE1 may be connected to the first active layer ACT1 and the second gate electrode GE2 of the second transistor T2. The first source electrode SE1 and the first drain electrode DE1 may be configured by a conductive material, such as copper (Cu), aluminum (Al), molybdenum (Mo), nickel (Ni), titanium (Ti), chrome (Cr), or an alloy thereof, but are not limited thereto.

The second transistor T2 is disposed on the buffer layer 111 in each of the plurality of sub pixels SP. The second transistor T2 is a transistor which supplies a driving current to the light emitting diode 130. The second transistor T2 is turned on to control the driving current flowing to the light emitting diode 130. Accordingly, the second transistor T2 which controls the driving current may be referred to as a driving transistor.

The second transistor T2 includes a second active layer ACT2, a second gate electrode GE2, a second source electrode SE2, and a second drain electrode DE2.

The second active layer ACT2 is disposed on the buffer layer 111. The second active layer ACT2 may be formed of a semiconductor material such as an oxide semiconductor, amorphous silicon, or polysilicon, but is not limited thereto.

The gate insulating layer 112 is disposed on the second active layer ACT2 and the second gate electrode GE2 is disposed on the gate insulating layer 112. The second gate electrode GE2 may be electrically connected to the first source electrode SE1 of the first transistor T1. The second gate electrode GE2 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the second gate electrode GE2 and the second source electrode SE2 and the second drain electrode DE2 which are electrically connected to the second active layer ACT2 are disposed on the interlayer insulating layer 113. The second drain electrode DE2 may be electrically connected to the second active layer ACT2 and the high potential power line VDD and the second source electrode SE2 may be electrically connected to the second active layer ACT2 and the light emitting diode 130. The second source electrode SE2 and the second drain electrode DE2 may be configured by a conductive material, such as copper (Cu), aluminum (Al), molybdenum (Mo), nickel (Ni), titanium (Ti), chrome (Cr), or an alloy thereof, but are not limited thereto.

The third transistor T3 is disposed on the buffer layer 111 in each of the plurality of sub pixels SP. The third transistor T3 is a transistor for compensating for a threshold voltage of the second transistor T2. The third transistor T3 is connected between the second source electrode SE2 of the second transistor T2 and the reference line RL. The third transistor T3 is turned on to transmit the reference voltage to the second source electrode SE2 of the second transistor T2 to sense a threshold voltage of the second transistor T2. Accordingly, the third transistor T3 which senses a characteristic of the second transistor T2 may be referred to as a sensing transistor.

The third transistor T3 includes a third active layer ACT3, a third gate electrode GE3, a third source electrode SE3, and a third drain electrode DE3.

The third active layer ACT3 is disposed on the buffer layer 111. The third active layer ACT3 may be formed of a semiconductor material such as an oxide semiconductor, amorphous silicon, or polysilicon, but is not limited thereto.

The gate insulating layer 112 is disposed on the third active layer ACT3 and the third gate electrode GE3 is disposed on the gate insulating layer 112. The third gate electrode GE3 may be electrically connected to the scan line SL. The third gate electrode GE3 may be configured by a conductive material, such as copper (Cu), aluminum (Al), molybdenum (Mo), nickel (Ni), titanium (Ti), chrome (Cr), or an alloy thereof, but is not limited thereto.

The interlayer insulating layer 113 is disposed on the third gate electrode GE3 and the third source electrode SE3 and the third drain electrode DE3 which are electrically connected to the third active layer ACT3 are disposed on the interlayer insulating layer 113. The third drain electrode DE3 may be electrically connected to the third active layer ACT3 and the reference line RL and the third source electrode SE3 may be electrically connected to the third active layer ACT3 and the second source electrode SE2 of the second transistor T2. The third source electrode SE3 and the third drain electrode DE3 may be configured by a conductive material, such as copper (Cu), aluminum (Al), molybdenum (Mo), nickel (Ni), titanium (Ti), chrome (Cr), or an alloy thereof, but are not limited thereto.

Next, the second capacitor electrode SC2 is disposed on the gate insulating layer 112. The second capacitor electrode SC2 is one of electrodes which form the storage capacitor Cst and may be disposed to overlap the first capacitor electrode SC1. The second capacitor electrode SC2 is integrally formed with the second gate electrode GE2 of the second transistor T2 to be electrically connected to the second gate electrode GE2. The first capacitor electrode SC1 and the second capacitor electrode SC2 may be disposed to be spaced apart from each other with the buffer layer 111 and the gate insulating layer 112 therebetween.

The plurality of scan lines SL, the auxiliary high potential power line VDDA, and a third capacitor electrode SC3 are disposed on the interlayer insulating layer 113.

First, the scan line SL is a wiring line which transmits the scan signal to each of the plurality of sub pixels SP. The scan line SL may extend in the row direction while traversing the plurality of sub pixels SP. The scan line SL may be electrically connected to the first gate electrode GE1 of the first transistor T1 and the third gate electrode GE3 of the third transistor T3 of each of the plurality of sub pixels SP.

An auxiliary high potential power line VDDA is disposed on the interlayer insulting layer 113. The auxiliary high potential power line VDDA extends in the row direction to traverse the plurality of sub pixels SP. The auxiliary high potential power line VDDA may be electrically connected to the high potential power line VDD extending in the column direction and the second drain electrode DE2 of the second transistor T2 of each of the plurality of sub pixels SP disposed along the row direction.

The third capacitor electrode SC3 is disposed on the interlayer insulating layer 113. The third capacitor electrode SC3 is an electrode which forms the storage capacitor Cst and may be disposed to overlap the first capacitor electrode SC1 and the second capacitor electrode SC2. The third capacitor electrode SC3 may be integrally formed with the second source electrode SE2 of the second transistor T2 to be electrically connected to the second source electrode SE2. The second source electrode SE2 may be electrically connected to the first capacitor electrode SC1 through a contact hole formed in the interlayer insulating layer 113 and the buffer layer 111. Therefore, the first capacitor electrode SC1 and the third capacitor electrode SC3 may be electrically connected to the second source electrode SE2 of the second transistor T2.

The storage capacitor Cst stores a potential difference between the second gate electrode GE2 and the second source electrode SE2 of the second transistor T2 while the light emitting diode 130 emits light, so that a constant current may be supplied to the light emitting diode 130. The storage capacitor Cst includes the first capacitor electrode ST1, the second capacitor electrode SC2, and the third capacitor electrode SC3 to store a voltage between the second gate electrode GE2 and the second source electrode SE2 of the second transistor T2. The first capacitor electrode ST1 is formed on the substrate 110 and is connected to the second source electrode SE2 and the second capacitor electrode ST2 is formed on the buffer layer 111 and the gate insulating layer 112 and is connected to the second gate electrode GE2. The third capacitor electrode ST3 is formed on the interlayer insulating layer 113 and is connected to the second source electrode SE2.

The first passivation layer 114 is disposed on the first transistor T1, the second transistor T2, the third transistor T3, and the storage capacitor Cst. The first passivation layer 114 is an insulating layer which protects components below the first passivation layer 114 and may be configured by a single layer or a double layer of silicon oxide SiOx or silicon nitride SiNx, but is not limited thereto.

The first planarization layer 115 is disposed on the first passivation layer 114. The first planarization layer 115 may planarize an upper portion of the substrate 110 on which the plurality of transistors and the storage capacitor Cst are disposed. The first planarization layer 115 may be configured by a single layer or a double layer, and for example, may be formed of photoresist or an acrylic organic material, but is not limited thereto.

The second passivation layer 116 is disposed on the first planarization layer 115. The second passivation layer 116 is an insulating layer which protects components below the second passivation layer 116 and may be configured by a single layer or a double layer of silicon oxide SiOx or silicon nitride SiNx, but is not limited thereto.

A connection electrode 120 and a plurality of low potential power lines VSS are disposed on the second passivation layer 116.

First, the connection electrode 120 is disposed in each of the plurality of sub pixels SP. The connection electrode 120 is an electrode which electrically connects the second transistor T2 and the pixel electrode PE. The connection electrode 120 may be electrically connected to the second source electrode SE2 which also serves as the third capacitor electrode SC3 through a contact hole formed in the second passivation layer 116, the first planarization layer 115, and the first passivation layer 114.

The connection electrode 120 may have a double-layered structure formed by a first connection layer 120a and a second connection layer 120b. The first connection layer 120a is disposed on the second passivation layer 116 and the second connection layer 120b which covers the first connection layer 120a is disposed. The second connection layer 120b may be disposed to enclose all a top surface and side surfaces of the first connection layer 120a. The second connection layer 120b is formed of a material which is more resistant to corrosion than the first connection layer 120a so that when the display device 100 is manufactured, the short defect due to the migration between the first connection layer 120a and the adjacent wiring line may be minimized. For example, the first connection layer 120a may be formed of a conductive material, such as copper (Cu) or chrome (Cr) and the second connection layer 120b may be formed of molybdenum (Mo) or titanium molybdenum (MoTi), but are not limited thereto.

A plurality of low potential power lines VSS is disposed on the second passivation layer 116. The plurality of low potential power lines VSS is wiring lines which transmit a low potential power voltage to the light emitting diode 130. The plurality of low potential power lines VSS may extend in the column direction in each of the plurality of sub pixels SP. For example, one pair of low potential power lines VSS which are spaced apart from each other with a predetermined interval may be disposed in each of the first sub pixel SP1, the second sub pixel SP2, and the third sub pixel SP3.

Each of the plurality of low potential power lines VSS includes a conductive layer VSSa and a clad layer VSSb. The conductive layer VSSa is disposed on the second passivation layer 116 and the clad layer VSSb which covers all the top surface and the side surfaces of the conductive layer VSSa is disposed on the conductive layer VSSa. For example, the conductive layer VSSa may be formed of a conductive material, such as copper (Cu) and chrome (Cr). The clad layer VSSb may be formed of a material which is more resistant to corrosion than the conductive layer VSSa, for example, molybdenum (Mo) or titanium molybdenum (MoTi), but is not limited thereto.

A third passivation layer 117 is disposed on the connection electrode 120 and the low potential power line VSS. The third passivation layer 117 is an insulating layer which protects components below the third passivation layer 117 and may be configured by a single layer or a double layer of silicon oxide SiOx or silicon nitride SiNx, but is not limited thereto.

Next, the plurality of light emitting diodes 130 is disposed on the third passivation layer 117. One or more light emitting diodes 130 are disposed in one sub pixel SP. The light emitting diode 130 is an element which emits light by the current. The light emitting diode 130 may include a light emitting diode 130 which emits red light, green light, and blue light and may implement various color light including white by a combination thereof. Further, various color light may be implemented using the light emitting diode 130 which emits specific color light and a light conversion member which converts light from the light emitting diode 130 into another color light. The light emitting diode 130 is electrically connected between the second transistor T2 and the low potential power line VSS to be supplied with a driving current from the second transistor T2 to emit light.

At this time, the plurality of light emitting diodes 130 disposed in one sub pixel SP may be connected in parallel. That is, one electrode of each of the plurality of light emitting diodes 130 may be connected to the same source electrode of the second transistor T2 and the other electrode may be connected to the same low potential power line VSS.

In the meantime, the light emitting diode 130 disposed in each of the plurality of sub pixels SP may emit different color light. For example, a light emitting diode 130 disposed in the first sub pixel SP1 may be a red light emitting diode, a light emitting diode 130 disposed in the second sub pixel SP2 may be a green light emitting diode, and a light emitting diode 130 disposed in the third sub pixel SP3 may be a blue light emitting diode. However, the light emitting diode 130 disposed in each of the plurality of sub pixels SP may emit the same color light, but is not limited thereto.

In the meantime, the light emitting diode 130 disposed in each of the plurality of sub pixels SP may have a different size. For example, the light emitting diode 130 of the first sub pixel SP1 has the largest size, the light emitting diode 130 of the third sub pixel SP3 has the smallest size, and the light emitting diode 130 of the second sub pixel SP2 has a medium size. The light emitting diodes 130 of the plurality of sub pixels SP have different sizes and different luminous efficiencies so that the design of the second transistor T2 for driving the light emitting diodes may also be different. For example, the second transistor T2 of the first sub pixel SP1 for driving the light emitting diode 130 may include a second active layer ACT2 having the largest size and the second transistor T2 of the third sub pixel SP3 may include a second active layer ACT2 having the smallest size. However, the size of the light emitting diode 130 is illustrative and all the light emitting diodes 130 may have the same size or may have different sizes, but are not limited thereto.

Even though in FIG. 4, for the convenience of description, it is illustrated that two light emitting diodes 130 are disposed in each of the plurality of sub pixels SP, the number of light emitting diodes 130 which are disposed in each of the plurality of sub pixels SP is not limited thereto. Referring to FIG. 5 again, the light emitting diode 130 includes a first semiconductor layer 131, an emission layer 132, a second semiconductor layer 133, a first electrode 134, a second electrode 135, and an encapsulation layer 136.

The first semiconductor layer 131 is disposed on the third passivation layer 117 and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers formed by doping p type or n type impurities into a material, such as gallium nitride (GaN), indium aluminum phosphide (InAlP), or gallium arsenide (GaAs). The p-type impurity may be magnesium (Mg), zinc (Zn), beryllium (Be), and the like, and the n-type impurity may be silicon (Si), germanium (Ge), tin (Sn), and the like, but are not limited thereto.

A part of the first semiconductor layer 131 may be disposed to outwardly protrude from the second semiconductor layer 133. A top surface of the first semiconductor layer 131 may be formed by a part overlapping a bottom surface of the second semiconductor layer 133 and a part disposed at an outside of the bottom surface of the second semiconductor layer 133. However, sizes and shapes of the first semiconductor layer 131 and the second semiconductor layer 133 may be modified in various forms, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), or the like, but is not limited thereto.

The first electrode 134 which encloses a bottom surface and side surfaces of the first semiconductor layer 131 is disposed. The first electrode 134 is an electrode which electrically connects the light emitting diode 130 and the low potential power line VSS. The first electrode 134 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the top surface of the second semiconductor layer 133. The second electrode 135 is an electrode which electrically connects a pixel electrode PE to be described below and the second semiconductor layer 133. The second electrode 135 may be formed of a conductive material, for example, a transparent conductive material, such as indium tin oxide (ITO) or indium zinc oxide (IZO), but is not limited thereto.

The encapsulation layer 136 which encloses at least a part of the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. The encapsulation layer 136 is disposed so as to cover the emission layer 132, a part of a side surface of the first semiconductor layer 131 adjacent to the emission layer 132, and a part of a side surface of the second semiconductor layer 133 adjacent to the emission layer 132. The first electrode 134 and the second electrode 135 may be exposed from the encapsulation layer 136 and a contact electrode CE and a pixel electrode PE to be formed later and the first electrode 134 and the second electrode 135 may be electrically connected.

Next, an adhesive layer AD is disposed between the plurality of light emitting diodes 130 and the third passivation layer 117. The adhesive layer AD may be an organic film which temporarily fixes the light emitting diode 130 during the self-assembling process of the light emitting diode 130. When the display device 100 is manufactured, if an organic film which covers the light emitting diode 130 is formed, a part of the organic film is filled in a space between the light emitting diode 130 and the third passivation layer 117 to temporarily fix the light emitting diode 130 onto the third passivation layer 117. Thereafter, even though the organic film is removed, a part of the organic film which permeates under the light emitting diode 130 remains without being removed to become an adhesive layer AD. The adhesive layer AD may be formed of an organic material, for example, photoresist or an acrylic organic material, but is not limited thereto.

Specifically, in the display device 100 according to the exemplary embodiment of the present disclosure, the plurality of light emitting diodes 130 may be self-assembled on the substrate 110 using a plurality of low potential power lines VSS. The plurality of light emitting diodes 130 is dielectrically polarized by the electric field to have a polarity. Therefore, the plurality of light emitting diodes 130 may move or be fixed to a specific direction by an electric field and the plurality of light emitting diodes 130 may be easily transferred onto the display device 100 using this characteristic.

Specifically, the light emitting diode 130 is inserted into a chamber which is filled with fluid and different voltages are applied to one pair of low potential power lines VSS to form an electric field. The light emitting diode 130 which is dielectrically polarized by the electric field may move or may be fixed to a specific direction by dielectrophoresis (DEP), that is, an electric field. The plurality of light emitting diodes 130 may be self-assembled on one pair of low potential power lines VSS using dielectrophoresis. When the self-assembling of the light emitting diode 130 is completed, other configurations, such as an adhesive layer AD, a contact electrode CE, a second planarization layer 118, and a pixel electrode PE, are formed to complete the manufacturing process of the display device 100.

Referring to FIG. 5 again, the contact electrode CE is disposed on the side surface of the light emitting diode 130. The contact electrode CE is an electrode for electrically connecting the light emitting diode 130 and the low potential power line VSS. The contact electrode CE may be electrically connected to the low potential power line VSS through a contact hole formed in the third passivation layer 117. The contact electrode CE is disposed so as to enclose at least a part of the first semiconductor layer 131 and the first electrodes 134 of the light emitting diode 130 to electrically connect the first semiconductor layer 131 and the first electrode 134 and the low potential power line VSS.

Next, a second planarization layer 118 is disposed on the light emitting diode 130 and the contact electrode CE. The second planarization layer 118 may planarize an upper portion of the substrate 110 in which the light emitting diode 130 is disposed and may fix the light emitting diode 130 onto the substrate 110 together with the adhesive layer AD. The second planarization layer 118 may be configured by a single layer or a double layer, and for example, may be formed of photoresist or an acrylic organic material, but is not limited thereto.

A first contact hole CH1 which exposes an upper portion of the light emitting diode 130 and a second contact hole CH2 which exposes the connection electrode 120 are formed in the second planarization layer 118. The second electrode 135 of the light emitting diode 130 may be exposed from the first contact hole CH1 and the connection electrode 120 may be exposed from the second contact hole CH2. At this time, a cross-sectional shape of the first contact hole CH1 may have a step shape. An inner side surface of the first contact hole CH1 may have a step shape. The first contact hole CH1 may be formed in a step shape in which a width is gradually narrowed from an upper portion of the first contact hole CH1 to a lower portion thereof.

In the display device 100 according to the exemplary embodiment of the present disclosure, the first contact hole CH1 which exposes the upper portion of the light emitting diode 130 is formed in a step shape to minimize a contact defect of the pixel electrode PE and the light emitting diode 130.

A depth of the first contact hole CH1 may be deeper as it is closer to the center of the first contact hole CH1. An overall size of the first contact hole CH1 may be larger than the light emitting diode 130. On the plane, an area of the light emitting diode 130 exposed through the first contact hole CH1 may be smaller than the entire area of the light emitting diode 130. The light emitting diode 130 may be exposed only at the center of the first contact hole CH1 having the deepest depth. The light emitting diode 130 is exposed from the second planarization layer 118 at the center of the first contact hole CH1 and the second planarization layer 118 may cover the light emitting diode 130 at an outer peripheral portion of the first contact hole CH1.

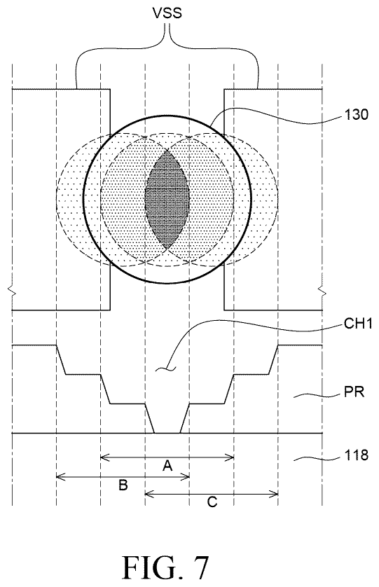

The first contact hole CH1 having a step shape may be formed by a plurality of exposure processes, which will be described in more detail with reference to FIG. 7.

The pixel electrode PE is disposed on the second planarization layer 118. The pixel electrode PE is an electrode which electrically connects the plurality of light emitting diodes 130 and the connection electrode 120. The pixel electrode PE may be electrically connected to the light emitting diode 130, the connection electrode 120, and the second transistor T2 through the first contact hole CH1 and the second contact hole CH2 formed in the second planarization layer 118.

At this time, the pixel electrode PE formed on the first contact hole CH1 may be also formed to have a step shape corresponding to the first contact hole CH1. The light emitting diode 130 is exposed from the second planarization layer 118 only at the center of the first contact hole CH1 so that the pixel electrode PE and the light emitting diode 130 may be in contact with each other only in a partial area of the first contact hole CH1.

Accordingly, the second electrode 135 of the light emitting diodes 130, the connection electrode 120, and the second source electrode SE2 of the second transistor T2 may be electrically connected to each other by means of the pixel electrode PE. The pixel electrode PE may be formed of a conductive material, for example, a transparent conductive material, such as indium tin oxide (ITO) or indium zinc oxide (IZO), but is not limited thereto.

Referring to FIG. 6, the plurality of link lines LL and the plurality of pad electrodes PAD disposed in the non-active area NA may be formed of the same process with the same material as configurations formed in the active area AA.

The plurality of link lines LL may have a structure in which a plurality of link line layers disposed on different layers is connected. For example, each of the plurality of link lines LL may include a first link line layer LLa, a second link line layer LLb, a third link line layer LLc, and a fourth link line layer LLd. The first link line layer LLa is disposed between the substrate 110 and the buffer layer 111 and the second link line layer LLb is disposed between the interlayer insulating layer 113 and the first passivation layer 114. The third link line layer LLc is disposed between the second passivation layer 116 and the third passivation layer 117 and the fourth link line layer LLd is disposed on the second planarization layer 118.

The first link line layer LLa may be formed by the same process with the same material as the high potential power line VDD, the plurality of data lines DL, the reference line RL, the light shielding layer LS, and the first capacitor electrode SC1. The second link line layer LLb may be formed by the same process with the same material as the plurality of scan lines SL, the auxiliary high potential power line VDDA, and the third capacitor electrode SC3, the source electrode and the drain electrode of each of the plurality of transistors. The third link line layer LLc may be formed by the same process with the same material as the low potential power line VSS. The fourth link line layer LLd may be formed by the same process with the same material as the pixel electrode PE.

One end of the first link line layer LLa may be connected to the plurality of pad electrodes PAD and the other end may extends toward the active area AA and the gate driver GD. One end of the second link line layer LLb may be connected to the other end of the first link line layer LLa through a contact hole formed in the interlayer insulating layer 113 and the other end may extend toward the active area AA and the gate driver GD. One end of the third link line layer LLc may be connected to the other end of the second link line layer LLb through a contact hole formed in the second passivation layer 116 and the first planarization layer 115 and the other end may extend toward the active area AA and the gate driver GD. Finally, one end of the fourth link line layer LLd may be connected to the other end of the third link line layer LLc through a contact hole formed in the second planarization layer 118 and the third passivation layer 117 and the other end may be connected to any one of configurations formed in the active area AA and the gate driver GD.

Therefore, the link line LL disposed in the non-active area NA is configured by a plurality of link line layers formed with the same material by the same process as the configuration of the active area AA to electrically connect the link line LL and the configuration of the active area AA and the gate driver GD.

Even though it is not illustrated in the drawing, the plurality of pad electrodes PAD may be formed of the same material by the same process as one or more line layers of the first link line layer LLa, the second link line layer LLb, the third link line layer LLc, and the fourth link line layer LLd, but is not limited thereto.

Hereinafter, the first contact hole CH1 will be described in detail with reference to FIG. 7.

FIG. 7 is a view for explaining a forming process of a first contact hole of a display device according to an exemplary embodiment of the present disclosure. FIG. 7 simultaneously shows a plan view and a cross-sectional view of a region where a first contact hole CH1 is formed. In FIG. 7, for the convenience of description, only a photoresist pattern PR, a light emitting diode 130, a low potential power line VSS, and a second planarization layer 118 are schematically illustrated.

Referring to FIG. 7, the first contact hole CH1 having a step shape may be formed by a plurality of exposure processes. Specifically, in order to form the first contact hole CH1, a mask process may be performed. After forming the photoresist on the second planarization layer 118, a plurality of exposure processes and development processes are performed on the photoresist to form a step-shaped photoresist pattern PR. The second planarization layer 118 is etched using the photoresist pattern PR as a mask to form the first contact hole CH1.

Specifically, the second planarization layer 118 and the photoresist are formed on the entire surface of the substrate 110 on which the light emitting diode 130 is disposed. After disposing a mask having an opening on the photoresist, light is irradiated to perform the exposure process. At this time, a thickness of the photoresist pattern PR formed by the development process may vary depending on an exposure amount and a type of the photoresist.

The photoresist may be any one of a positive type and a negative type. In the positive photoresist, a photoresist may remain in an area in which the light is blocked by the mask and the photoresist may be removed from an area through which light passes. In contrast, in the negative photoresist, a photoresist may be removed from the area in which the light is blocked by the mask and the photoresist may remain in an area through which light passes. Hereinafter, it is assumed that the photoresist is a positive type in which a part irradiated with light during the exposure process is removed, but it is not limited thereto.

More photoresists may be removed according to an amount of light irradiated during the exposure process. For example, the exposure process may be performed by disposing a mask having an opening on the photoresist. In an area of the photoresist which overlaps the opening, a characteristic may vary by irradiated light and the area may be removed by a development process later. At this time, a part of the photoresist on which the light is not irradiated may remain as it is without being removed by the development process and the more the light is irradiated, the deeper the part is removed by the development process.

In the display device 100 according to the exemplary embodiment of the present disclosure, a plurality of exposure processes is performed in a plurality of areas to form a step-shaped first contact hole CH1. For example, after disposing the opening of the mask so as to overlap a center of the light emitting diode 130, the exposure process may be performed in an area A. The area A may be an area corresponding to the center of the light emitting diode 130.

Next, after shifting the mask by a predetermined distance in one side direction from the area A, the exposure process may be performed on an area B. The area B may partially overlap the area A. The overlapping area of the area A and the area B may overlap a center of the light emitting diode 130. When the exposure process is performed on the area B, light may be irradiated in the overlapping area of the area A and the area B twice.

After shifting the mask by a predetermined distance in the other side direction from the area A, the exposure process may be performed on the area C. The area A may be disposed between the area B and the area C. The area C may partially overlap the area A. The area C may also partially overlap an area B. The overlapping area of the area C and the area A and the area B may overlap a center of the light emitting diode 130. Accordingly, when the exposure process is performed on the area C, light may be irradiated in the overlapping area of the area A, the area B, and the area C three times.

Next, the development process is performed to pattern a photoresist layer. In the overlapping area of the area A, the area B, and the area C in which the most light is irradiated, more photoresist may be removed. In a remaining area of the area B which does not overlap the area A on which light is irradiated only once and a remaining area of the area C which does not overlap the area A, less photoresist may be removed. Accordingly, the photoresist may be patterned as a step-shaped photoresist pattern PR by the development process.

Thereafter, the second planarization layer 118 may be patterned using the photoresist pattern PR as a mask. The second planarization layer 118 may be etched with the deepest depth in the overlapping area of the area A, the area B, and the area C in which the largest number of exposures is performed, that is, at the center of the light emitting diode 130. Further, the second planarization layer 118 may be etched with the smallest depth in a part of an area of the area B and the area C which do not overlap the area A having the smallest number of exposures and a step-shaped first contact hole CH1 may be formed.

Accordingly, a combined area of the area A, the area B, and the area C in which the exposure process is performed is an area corresponding to the first contact hole CH1. In this case, the area of the first contact hole CH1 which is an exposure area extends to the outside of the area in which the light emitting diode 130 is disposed, but in the first contact hole CH1, only an upper portion of the light emitting diode 130 may be substantially exposed. That is, in the first contact hole CH1, a side portion of the light emitting diode 130 is not exposed, but only an upper portion of the light emitting diode 130 may be exposed.

If the size of the light emitting diode is smaller than a smallest size of the first contact hole which can be implemented by the process equipment or an alignment error of the first contact hole occurs, a side portion of the light emitting diode may be exposed through the first contact hole. A side surface of the light emitting diode is exposed through the first contact hole and a V-shaped groove may be formed between the side surface of the light emitting diode and the first contact hole. Specifically, when the first contact hole is larger than the light emitting diode, the V-shaped groove may be formed along a circumference of the light emitting diode. However, due to a steep slope of the V-shaped groove, the pixel electrode may be disconnected in the V-shaped groove and it may be difficult to electrically connect the pixel electrode to the light emitting diode.

Therefore, in the display device 100 according to the exemplary embodiment of the present disclosure, the first contact hole CH1 is formed by a triple repeated exposure method to expose only an upper portion of the light emitting diode 130 through the first contact hole CH1. the exposure process may be performed on the second planarization layer 118 which covers the light emitting diode 130 by shifting the mask by a predetermined interval. For example, the exposure process may be performed on the area A and the exposure may be performed on the area B which is partially shifted from the area A, and then the exposure process may be performed on the area C which is partially shifted from the area A and the area B. The exposure process may be performed in an area where the area A, the area B, and the area C overlap three times so that the first contact hole CH1 may be formed with the deepest depth. Accordingly, the first contact hole CH1 may be formed to have a different shape from the opening of the mask and have a smaller size. Accordingly, in the display device 100 according to the exemplary embodiment of the present disclosure, during the exposure process, an overlapping area is adjusted to design the size and the position of the first contact hole CH1 in various forms. Further, the disconnection of the pixel electrode PE due to the exposed side surface of the light emitting diode 130 in the first contact hole CH1 may be minimized.

Further, in the display device 100 according to the exemplary embodiment of the present disclosure, a contact hole with a smaller size than a contact hole formed in the process equipment may be formed. First, the light emitting diode 130 may be a micro LED having a micro size. In this case, when the minimum size of the contact hole which can be implemented by the process equipment is larger than the light emitting diode 130, the first contact hole CH1 is formed to be larger than the light emitting diode 130. Accordingly, defects that the side surface of the light emitting diode 130 is exposed, the pixel electrode PE is disconnected, or the pixel electrode PE is connected to both the first semiconductor layer 131 and the second semiconductor layer 133 may occur. However, in the display device 100 according to the exemplary embodiment of the present disclosure, a repeated exposure area is formed by shifting the mask so that a size of the contact hole may be formed to be smaller than an opening of the actual mask. Accordingly, the size and the shape of the first contact hole CH1 may be designed in various forms in consideration of the size of the light emitting diode 130 and the disconnection of the pixel electrode PE or short defect may be minimized.

In the display device 100 according to the exemplary embodiment of the present disclosure, contact holes having various shapes may be formed with only the existing mask, without using a halftone mask. When the size of the first contact hole CH1 needs to be adjusted according to a size of the light emitting diode 130, a mask for the exposure process needs to be newly manufactured. However, in the display device 100 according to the exemplary embodiment of the present disclosure, the repeated exposure area is formed by just shifting the mask to adjust the size and the shape of the first contact hole CH1 in various forms. Accordingly, the first contact hole CH1 may be formed only with the existing mask, without using a new mask or a halftone mask and a manufacturing cost may be saved.

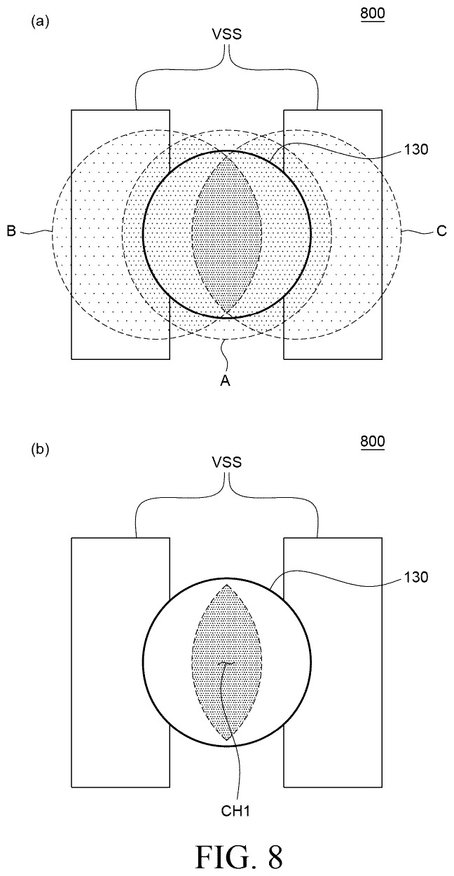

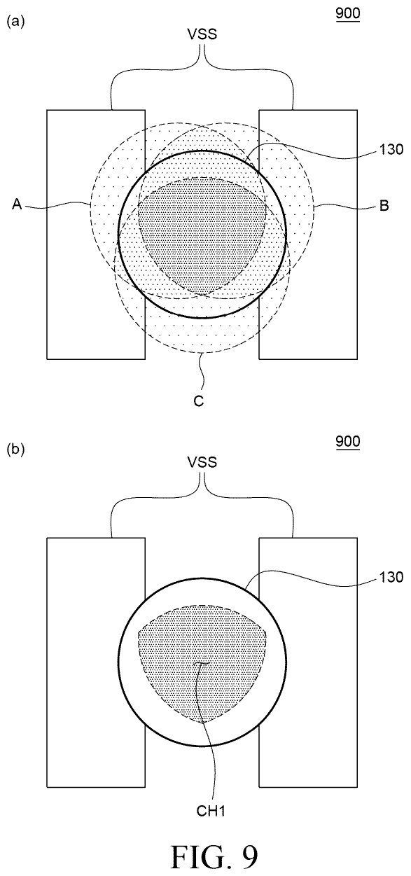

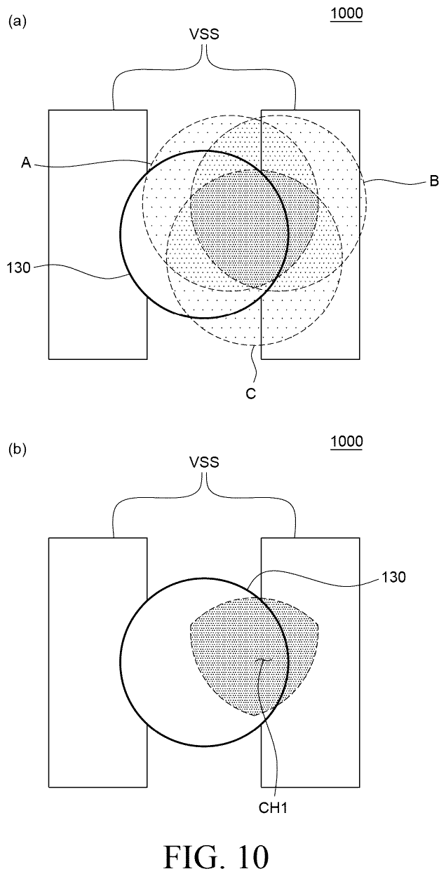

FIG. 8 is a schematic plan view of a display device according to another exemplary embodiment of the present disclosure. FIG. 9 is a schematic plan view of a display device according to still another exemplary embodiment of the present disclosure and FIG. 10 is a schematic plan view of a display device according to still another exemplary embodiment of the present disclosure. FIGS. 8 to 10 are plan views illustrating an area on which the exposure process is performed and a part of the light emitting diode 130 which is actually exposed in the first contact hole CH1. The only difference between display devices 800, 900, 1000 of FIGS. 8 to 10 and the display device 100 of FIGS. 1 to 7 is a shape of the first contact hole CH1, but the other configuration is substantially the same, so that a redundant description will be omitted. In FIGS. 8 to 10, for the convenience of description, only a low potential power line VSS, a light emitting diode 130, a first contact hole CH1, and an exposure area are illustrated.

Referring to FIG. 8, in the display device 800 according to another exemplary embodiment of the present disclosure, the first contact hole CH1 may be formed using a mask having an opening which is larger than the light emitting diode 130. For example, a photoresist is formed on the second planarization layer 118 and a first exposure process may be performed on the area A so as to correspond to the center of the light emitting diode 130. A second exposure process may be performed on the area B by partially shifting the mask to a left direction of the area A. A third exposure process may be performed on the area C by partially shifting the mask to a right direction of the area A. Finally, the development process is performed to form a step-shaped photoresist pattern PR and the etching process of the second planarization layer 118 is formed using the photoresist pattern PR as a mask to form a step-shaped first contact hole CH1 in the second planarization layer 118.

The area A, the area B, and the area C on which the exposure processes are performed correspond to the first contact hole CH1 and a combined area of the area A, the area B, and the area C may be defined as the first contact hole CH1. At this time, the overlapping area of the area A, the area B, and the area C on which the exposure process is performed three times may overlap only the light emitting diode 130. Accordingly, the area on which the exposure process is performed three times is a part of the first contact hole CH1 in which the light emitting diode 130 is actually exposed so that an overall size of the first contact hole CH1 may be larger than the light emitting diode 130. However, a size of the light emitting diode 130 which is exposed through the first contact hole CH1 may be smaller than the first contact hole CH1 and may also be smaller than the overall size of the light emitting diode 130.

Referring to FIG. 9, in the display device 900 according to still another exemplary embodiment of the present disclosure, the first contact hole CH1 may be formed by shifting the mask in various directions. For example, after performing the first exposure process on the area A, the second exposure process may be performed on the area B by shifting the mask to the right direction of the area A. A third exposure process may be performed on the area C by shifting the mask to a downward direction of the area A and the area B. Accordingly, the exposure process may be performed by shifting the mask in various directions such as up, down, left, and right directions to form the first contact hole CH1 with various forms.

Referring to FIG. 10, in the display device 1000 according to still another exemplary embodiment of the present disclosure, the first contact hole CH1 may be formed in various positions by a plurality of exposure processes. For example, the first contact hole CH1 and the light emitting diode 130 may be asymmetrically formed. When an overlapping area of the area A, the area B, and the area C of the photoresist on which the exposure process is performed is asymmetrically disposed with the light emitting diode 130, the first contact hole CH1 may be also asymmetrically formed with the light emitting diode 130. A center of the first contact hole CH1 may be deviated from the center of the light emitting diode 130. In this case, a side surface of the light emitting diode 130 may be partially exposed but in a part of the first contact hole CH1 corresponding to an upper portion of the light emitting diode 130, the pixel electrode PE and the light emitting diode 130 may be normally connected. Specifically, the size of the light emitting diode 130 which is actually exposed through the first contact hole CH1 is formed to be smaller than the overall size of the light emitting diode 130. Accordingly, the pixel electrode PE may be normally connected while suppressing the formation of the V-shaped groove along the entire circumference of the light emitting diode 130.

In the display device 800, 900, and 1000 according to various exemplary embodiments of the present disclosure, the first contact hole CH1 may be designed in various forms by means of an area in which the exposure process is repeatedly performed. For example, even though the opening of the mask is larger than the light emitting diode 130, the mask is shifted such that the exposure repeated area corresponds to only the light emitting diode 130. Therefore, the first contact hole CH1 having a smaller size than the light emitting diode 130 may be formed. As another example, the mask is shifted in various directions to form the first contact hole CH1 which is an exposure repeated area in various shapes. Further, as another example, the size of the exposure repeated area is formed to be smaller than the light emitting diode 130 and the exposure repeated area may be disposed in various forms such as an asymmetrical structure or a symmetrical structure with the light emitting diode 130. Accordingly, in the display devices 800, 900, and 100 according to various exemplary embodiments of the present disclosure, a first contact hole CH1 having various shapes may be manufactured with only one type of mask so that a degree of freedom of the design may be improved.

The exemplary embodiments of the present disclosure can also be described as follows:

According to an aspect of the present disclosure, there is provided a display device. The display device includes a substrate in which a plurality of sub pixels is defined, a light emitting diode disposed on the substrate in each of the plurality of sub pixels, and a planarization layer which covers the light emitting diode and includes a first contact hole overlapping the light emitting diode, the first contact hole is formed to have a width which is narrowed from an upper portion of the first contact hole toward a lower portion of the first contact hole.

The display device may further include a pixel electrode disposed on the light emitting diode in each of the plurality of sub pixels, the light emitting diode disposed in the plurality of sub pixels may be electrically connected to the pixel electrode through the first contact hole.

The pixel electrode and the light emitting diode may be in contact with each other in only a partial area of the first contact hole.

An inner side surface of the first contact hole may be formed to have a step shape.

Only an upper portion of the light emitting diode may be exposed through the first contact hole.

The closer to a center of the first contact hole, the deeper a depth of the first contact hole.

The light emitting diode may be exposed at a center of the first contact hole from the planarization layer, and the planarization layer may cover the light emitting diode at an outside of the first contact hole.

In plan view, an area of the first contact hole may be larger than an area of the light emitting diode and an area of the light emitting diode exposed through the first contact hole may be smaller than the area of the first contact hole.

In plan view, an area of the light emitting diode exposed through the first contact hole may be smaller than an overall area of the light emitting diode.

A center of the first contact hole may correspond to a center of the light emitting diode.

A center of the first contact hole may be deviated from a center of the light emitting diode.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate in which a plurality of sub pixels is defined;
a light emitting diode disposed on the substrate in each of the plurality of sub pixels; and
a planarization layer which covers the light emitting diode and includes a first contact hole overlapping the light emitting diode,
wherein the first contact hole is formed to have a width which is narrowed from an upper portion of the first contact hole toward a lower portion of the first contact hole.

2. The display device according to claim 1, further comprising:
a pixel electrode disposed on the light emitting diode in each of the plurality of sub pixels,
wherein the light emitting diode disposed in the plurality of sub pixels is electrically connected to the pixel electrode through the first contact hole.

3. The display device according to claim 2, wherein the pixel electrode and the light emitting diode are in contact with each other in only a partial area of the first contact hole.

4. The display device according to claim 1, wherein an inner side surface of the first contact hole is formed to have a step shape.

5. The display device according to claim 1, wherein only an upper portion of the light emitting diode is exposed through the first contact hole.

6. The display device according to claim 1, wherein the closer to a center of the first contact hole, the deeper a depth of the first contact hole.

7. The display device according to claim 6, wherein the light emitting diode is exposed at a center of the first contact hole from the planarization layer, and
the planarization layer covers the light emitting diode at an outside of the first contact hole.

8. The display device according to claim 1, wherein in plan view, an area of the first contact hole is larger than an area of the light emitting diode and an area of the light emitting diode exposed through the first contact hole is smaller than the area of the first contact hole.

9. The display device according to claim 8, wherein in plan view, an area of the light emitting diode exposed through the first contact hole is smaller than an overall area of the light emitting diode.

10. The display device according to claim 1, wherein a center of the first contact hole corresponds to a center of the light emitting diode.

11. The display device according to claim 1, wherein a center of the first contact hole is deviated from a center of the light emitting diode.
